(19) United States
(12) Patent Application Publication
(10) Pub. No.: US 2015/0287840 A1
(43) Pub. Date: Oct. 8, 2015

(54) SEMICONDUCTOR DEVICE

(71) Applicant: KABUSHIKI KAISHA TOSHIBA, Tokyo (JP)

(72) Inventors: Tsuyoshi OTA, Hyogo (JP); Yoichi HORI, Hyogo (JP); Takao NODA, Hyogo (JP)

(21) Appl. No.: 14/743,214

(22) Filed: Jun. 18, 2015

Related U.S. Application Data
(62) Division of application No. 14/186,694, filed on Feb. 21, 2014.

(30) Foreign Application Priority Data
Jul. 31, 2013 (JP) 2013-159637

(51) Int. Cl. H01L 29/872; H01L 29/417; H01L 29/06; H01L 29/16; H01L 23/00

(52) U.S. Cl. CPC H01L 29/872; H01L 29/1608; H01L 29/16; H01L 24/45; H01L 29/06; H01L 29/417

(57) ABSTRACT

A semiconductor device includes first and second electrodes. First semiconductor regions of a first conductivity type are positioned between the first electrode and the second electrode and contact the first electrode. These semiconductor regions are arranged along a first direction. A second semiconductor region of the first conductivity type also contacts the first electrode and is disposed around the plurality of first semiconductor regions. The second semiconductor region has a dopant concentration that is higher than the first semiconductor regions. A semiconductor layer of a second conductivity type has portions that are between the first semiconductor regions and the second semiconductor region. These portions are in Schottky contact with the first electrode.

### CROSS-REFERENCE TO RELATED APPLICATION

This application is a division of U.S. patent application Ser. No. 14/186,694, filed on Feb. 21, 2014, which is based upon and claims the benefit of priority from Japanese Patent Application No. 2013-159637, filed on Jul. 31, 2013, the entire contents of which are incorporated herein by reference.

### FIELD

Exemplary embodiments described herein relate generally to a semiconductor device.

### BACKGROUND

A Schottky barrier diode (SBD), in which an n-type semiconductor layer and a metal are in contact with each other, is a monopolar element, and thus an electron current flows between an anode and a cathode in an electric conduction state. Setting a resistivity of an n-type semiconductor layer to be high is one of the methods of setting a withstand (breakdown) voltage of such a SBD to be high. However, setting the resistivity of the n-type semiconductor layer to be high increases a forward voltage Vf. Furthermore, if a surge electric current flows, there is a likelihood of localized high voltages and generating heat within the element and causing destruction of the element due to the heat.

### DESCRIPTION OF THE DRAWINGS

FIG. 1A is a schematic plan view illustrating a semiconductor device according to a first embodiment, and FIG. 1B is a schematic cross-sectional view illustrating the semiconductor device according to the first embodiment.

FIG. 2A and FIG. 2B are schematic cross-sectional views, each illustrating operation of the semiconductor device according to the first embodiment.

FIG. 3A and FIG. 3B are schematic cross-sectional views, each illustrating the operation of the semiconductor device according to the first embodiment.

FIG. 4A is a schematic cross-sectional view illustrating a semiconductor device according to a second embodiment, and FIG. 4B is a schematic cross-sectional view illustrating the operation of the semiconductor device according to the second embodiment.

FIG. 5A is a schematic cross-sectional view illustrating the operation of the semiconductor device according to the second embodiment, and FIG. 5B is a schematic cross-sectional view illustrating the operation of the semiconductor device according to the second embodiment.

FIG. 6A is a schematic cross-sectional view illustrating a semiconductor device according to a third embodiment, FIG. 6B is a schematic cross-sectional view illustrating operation of the semiconductor device according to the third embodiment, and FIG. 6C is a schematic cross-sectional view illustrating the operation of the semiconductor device according to the third embodiment.

FIG. 7A is a schematic cross-sectional view illustrating a first example of a semiconductor device according to a fourth embodiment, and FIG. 7B is a schematic cross-section view illustrating a second example of the semiconductor device according to the fourth embodiment.

### DETAILED DESCRIPTION

Embodiments provide a semiconductor device in which the passage of a large electric current is possible and which has a high withstand (breakdown) voltage.

In general, according to one embodiment, a semiconductor device includes first and second electrodes. First semiconductor regions of a first conductivity type are positioned between the first electrode and the second electrode and are in contact with the first electrode. These first semiconductor regions are arranged along a first direction that intersects a second direction extending from the first electrode to the second electrode. A second semiconductor region of the first conductivity type also contacts the first electrode and is disposed around the plurality of first semiconductor regions. The second semiconductor region may form a closed or partial bounding region when viewed from a position perpendicular to a plane containing the first semiconductor regions. The second semiconductor region has a dopant concentration that is higher than the first semiconductor regions. A first semiconductor layer of a second conductivity type has portions that are between the first semiconductor regions and the second semiconductor region. These portions are in Schottky contact with the first electrode.

Exemplary embodiments are described below referring to the drawings. In the following description, the same reference numerals are given to like elements, and a description of a once-described element may be omitted in subsequent descriptions.

Furthermore, in the example embodiments, a semiconductor that is doped with p-type impurities (whether at p⁺-type, p-type, and p⁻-type levels) is referred to as a first conductivity type semiconductor, and a semiconductor that is doped with n-type impurities (whether at n⁺-type, n-type, n⁻-type levels) is referred to as a second conductivity type semiconductor. A “p⁺-type” semiconductor indicates impurities are at a higher concentration than a “p-type” semiconductor. Similarly, an “n⁺-type” semiconductor indicates impurities are at a higher concentration than an “n-type” semiconductor.

### First Embodiment

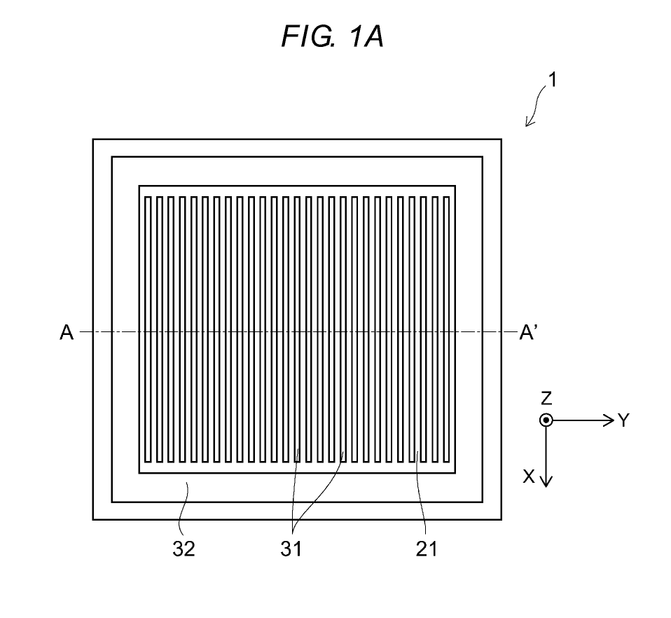

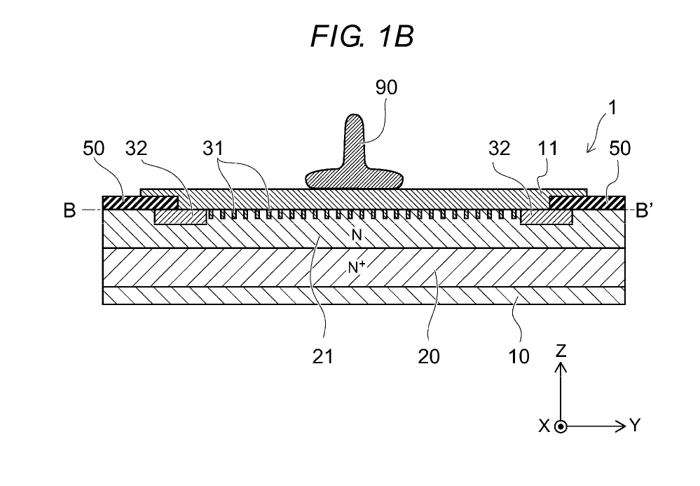

FIG. 1A is a schematic plan view illustrating a semiconductor device according to a first embodiment, and FIG. 1B is a schematic cross-sectional view illustrating the semiconductor device according to the first embodiment. In FIG. 1A, an anode electrode 11, an insulating layer 50 and a bonding wire 90 are not specifically depicted, but these elements are depicted in FIG. 1B.

FIG. 1A illustrates a cross section taken along line B-B′ in FIG. 1B. FIG. 1B illustrates a cross section taken along line A-A′ in FIG. 1A.

A semiconductor device 1 depicted in FIG. 1A and FIG. 1B has a Schottky barrier diode (SBD). The semiconductor device 1 includes an anode electrode 11 (a first electrode), a cathode electrode 10 (a second electrode), multiple p-type semiconductor regions 31 (a first semiconductor region), a p⁺-type semiconductor region 32 (a second semiconductor region), an n-type semiconductor layer 21 (a first semiconductor layer), and an n⁺-type semiconductor layer 20. Furthermore, a bonding wire 90, is connected to the anode electrode 11, as illustrated in FIG. 1B. A direction from the anode electrode 11 toward the cathode electrode 10 is defined as a Z-direction (a second direction). A direction that intersects the Z-direction is defined as an X-direction, and a direction that intersects the X-direction (third direction) and the Z-direction is defined as a Y-direction (a first direction).

Multiple p-type semiconductor regions 31, arranged along the Y-direction, are low-concentration p-type layers. Each p-type semiconductor region 31 is positioned between the anode electrode 11 and the cathode electrode 10 and is in contact with the anode electrode 11. The p-type semiconductor regions 31 may extend as stripes (e.g., a continuous pattern) in the X-direction.

Each of the p-type semiconductor regions 31 may be arranged in the shape of an island on a two-dimensional plane encompassing the X-direction and the Y-direction. Furthermore, a planar shape of each island may be polygonal or circular when the p-type semiconductor region 31 is arranged as islands. That is, one or more p-type semiconductor region 31 may extend in the X-direction in an intermittent pattern (e.g., a dotted and/or dashed line)

The p⁺-type semiconductor region 32 is a high-concentration p⁺-type layer. The p⁺-type semiconductor region 32 is positioned between the anode electrode 11 and the cathode electrode 10 and is in contact with the anode electrode 11. A dopant concentration of the p⁺-type semiconductor region 32 is higher than the dopant concentrations of the p-type semiconductor regions 31. The p⁺-type semiconductor region 32 is, for example, in ohmic contact with the anode electrode 11.

In FIG. 1A, the p⁺-type semiconductor region 32 is arranged in such a manner as to bound the p-type semiconductor regions 31 in the X-Y plane. A distance between the p⁺-type semiconductor region 32 and the cathode electrode 10 is less than a distance between the p-type semiconductor regions 31 and the cathode electrode 10. That is p-type semiconductor regions 31 are shallower in the Z-direction than the p⁺-type semiconductor region 32. A ring-shaped p⁺-type semiconductor region 32 is illustrated in FIG. 1A, but a construction of the p⁺-type semiconductor region 32 may be such that some portions of the p⁺-type semiconductor region 32 are broken off and a closed ring-shape for region 32 is not required.

The n-type semiconductor layer 21 is a low-concentration n-type layer. The n-type semiconductor layer 21 is provided between the anode electrode 11 and the cathode electrode 10, and between the p-type semiconductor regions 31 and the p⁺-type semiconductor region 32. The n-type semiconductor layer 21 is in Schottky-type contact with the anode electrode 11. In the semiconductor device 1, a Schottky barrier is formed between the anode electrode 11 and the n-type semiconductor layer 21 during an off-state (non-conductance state). Furthermore, the n-type semiconductor layer 21 is in contact with each of the multiple p-type semiconductor regions 31. Accordingly, the semiconductor device 1 has a p-n junction region that is made by the n-type semiconductor layer 21 contacting a p-type semiconductor region 31.

The n⁺-type semiconductor layer 20 is a high-concentration n⁺-type layer. The n⁺-type semiconductor layer 20 is provided between the n-type semiconductor layer 21 and the cathode electrode 10. The n⁺-type semiconductor layer 20 is in ohmic contact with the cathode electrode 10.

The insulating layer 50 is provided between the anode electrode 11 and a portion of n-type semiconductor layer 21 and between the anode electrode 11 and a portion the p⁺-type semiconductor region 32. The insulating layer 50 includes, for example, silicon oxide (SiO₂).

A material of each of the p-type semiconductor regions 31, the p⁺-type semiconductor region 32, the n-type semiconductor layer 21, and the n⁺-type semiconductor layer 20 includes, for example, silicon crystal (Si). Each silicon crystal region can be doped with dopant elements. In this case, for example, boron (B), Ga (gallium), or Al (aluminum) is doped as the dopant element for a conductivity type (a first conductivity type) such as a p⁺-type and a p-type. For example, phosphorous (P), arsenic (As), or nitrogen (N) may be doped as the dopant element to provide a conductivity type (a second conductivity type) such as an n⁺-type and an n-type.

Furthermore, a material of the semiconductor regions/layers is not limited to silicon, and each of the p-type semiconductor region 31, the p⁺-type semiconductor region 32, the n-type semiconductor layer 21, and the n⁺-type semiconductor layer 20 may include, for example, a silicon carbide crystal (SiC).

If the material of the semiconductor is silicon, a concentration of the dopant element that is included in the p⁺-type layer and the n⁺-type layer is 3×10¹⁷ or more (atoms·cm⁻³). A concentration of the dopant element that is included in the p-type layer and the n-type layer is, for example, 3×10¹⁷ or less (atoms·cm⁻³).

Dopant concentrations of the p⁺-type layer, the n⁺-type layer, the p-type layer, and the n-type layer may be set at an arbitrary dopant concentration level according to the requirements of specific designs of the device.

According to the embodiment, the “concentration of the dopant element (the dopant concentration)” refers to an effective concentration of the dopant element that contributes to conductivity of the semiconductor material. For example, if the dopant element that is an electron donor and the dopant element that is an electron acceptor are both included in the semiconductor material, a concentration that is obtained after the donor and the acceptor offset each other in the activated device element is the dopant concentration.

A material of the cathode electrode 10 and a material of the anode electrode 11 may include at least one material that is selected from a group including aluminum (Al), titanium (Ti), nickel (Ni), tungsten (W), and gold (Au). Other materials may also be suitable for a material of the cathode electrode 10 and a material of the anode electrode 11.

Operation of the semiconductor device 1 is described.

According to an embodiment, an energy barrier that is based on the Schottky contact between the anode electrode 11 and the n-type semiconductor layer 21 is referred to as a Schottky barrier. Furthermore, an energy barrier that is based on a p-n junction between the p⁺-type semiconductor region 32 and the n-type semiconductor layer 21 is referred to as a p-n energy barrier.

In the semiconductor device 1, the p-n energy barrier is set to be equal in height to the Schottky barrier, or to be greater in height than the Schottky barrier. As one example, a case where the p-n energy barrier is set to be greater in height than the Schottky barrier is described below.

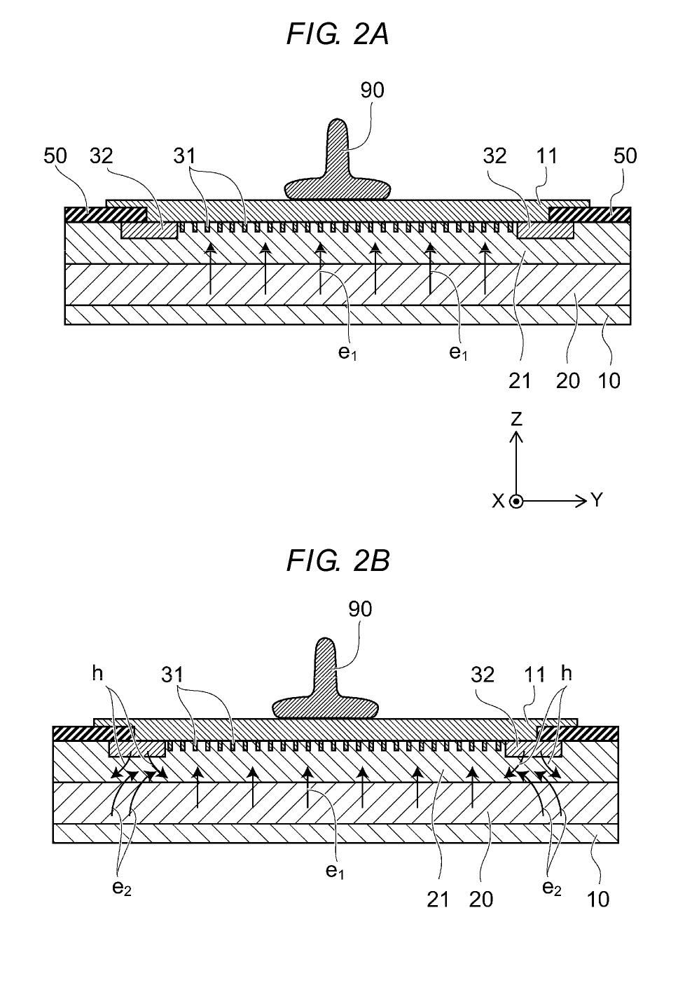

FIG. 2A and FIG. 2B are schematic cross-sectional views, each illustrating the operation of the semiconductor device according to the first embodiment.

As illustrated in FIG. 2A, a voltage V₁ is applied between the cathode and the anode in such a manner that an electric potential of the anode electrode 11 is greater than an electric potential of the cathode electrode 10. To put it another way, a forward bias is applied between the cathode and the anode. In this case, the Schottky barrier between the anode electrode 11 and the n-type semiconductor layer 21 is lowered, and thus electrons e1 that are injected from the cathode electrode 10 into the n⁺-type semiconductor layer 20 flow through the n-type semiconductor layer 21 to the anode electrode 11.

At this stage, an electric current does not flow between the p⁺-type semiconductor region 32 and the n-type semiconductor layer 21. In the semiconductor device 1, although the voltage V₁ is applied between the cathode and the anode, a dopant concentration of the p⁺-type semiconductor region 32 and a dopant concentration of the n-type semiconductor layer 21 are set in such a manner that the electric current does not flow through the p-n junction between the p⁺-type semiconductor region 32 and the n-type semiconductor layer 21.

Subsequently, as illustrated in FIG. 2B, a higher voltage V₂ is applied between the cathode and the anode in such a manner that the electric potential of the anode electrode 11 is greater than the electric potential of the cathode electrode 10. That is, an expression can be written as an absolute value of V₂>an absolute value of V₁.

In this case, the Schottky barrier is further lowered between the anode electrode 11 and the n-type semiconductor layer 21. Accordingly, electrons e1 that are injected from the cathode electrode 10 into the n⁺-type semiconductor layer 20 flow through the n-type semiconductor layer 21 to the anode electrode 11.

On the other hand, if the voltage V₂ is applied between the cathode and the anode, the p-n energy barrier between the p⁺-type semiconductor region 32 and the n-type semiconductor layer 21 is also lowered. Accordingly, carriers (holes h) are injected from the high-concentration p⁺-type semiconductor region 32 into the n-type semiconductor layer 21.

When these carriers are injected into the n-type semiconductor layer 21, conductivity modulation in which resistance of the n-type semiconductor layer 21 is lowered for the electrons occurs in a portion of the n-type semiconductor layer 21 into which the carriers are injected. Therefore, the portion of the n-type semiconductor layer 21 into which the carriers are injected is a layer that is low in resistance for the electrons, and thus the electrons flow more easily through this region. The electrons that flow to the portion of n-type semiconductor layer 21 are indicated by electrons e2 in the drawings. To put it another way, the number of electrons that can be injected from the cathode electrode 10 into the n⁺-type semiconductor layer 20 is increased in the state in FIG. 2B, compared to the state in FIG. 2A. In other words, an amount of electric current flowing between the cathode and anode electrodes is increased in the state in FIG. 2B, compared to the state in FIG. 2A.

In this manner, in the semiconductor device 1, a large electric current can flow between the cathode and anode electrodes by modulating conductivity by applying a forward bias. Moreover, even if the p-n energy barrier and the Schottky barrier are at the same height, the state illustrated in FIG. 2B is still obtained when applying the voltage V₂.

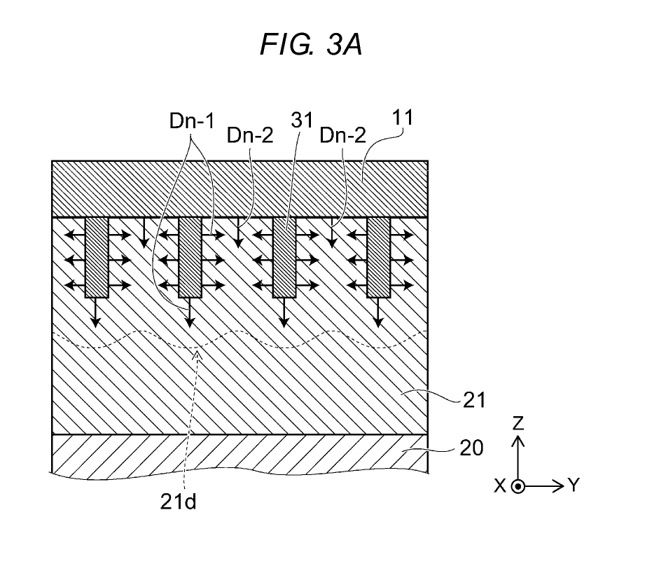

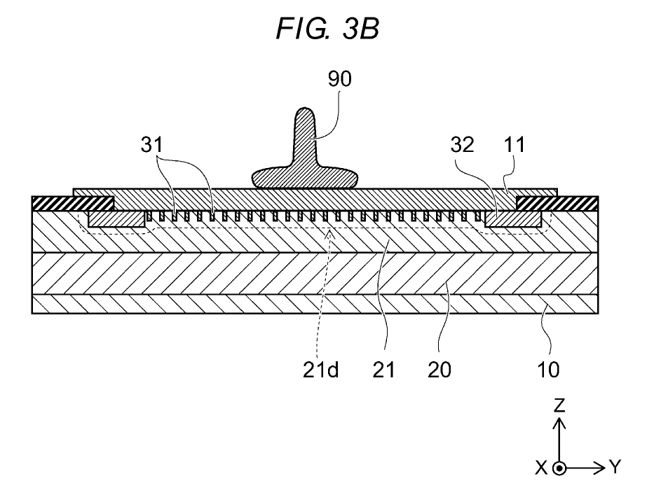

FIG. 3A and FIG. 3B are schematic cross-sectional views, each illustrating the operation of the semiconductor device according to the first embodiment. FIG. 3A is an enlarged view that is obtained by enlarging a portion of the vicinity of the p-type semiconductor region 31 depicted in FIG. 3B.

As illustrated in FIG. 3A and FIG. 3B, when a voltage −V₃ is applied between the cathode electrode and the anode electrode in such a manner that the electric potential of the anode electrode 11 is smaller than the electric potential of the cathode electrode 10. To put it another way, a reverse bias is applied between the cathode and the anode.

When the reverse bias is applied between the cathode and the anode, a depletion layer that extends from a junction interface between the cathode electrode 10 and the n-type semiconductor layer 21 into the n-type semiconductor layer 21 is formed. Moreover, the depletion layer extends also from the p-n junction region between the p-type semiconductor region 31 and the n-type semiconductor layer 21 to each of the p-type semiconductor region 31 and the n-type semiconductor layer 21. Furthermore, the depletion layer extends from the junction region between the anode electrode 11 and the n-type semiconductor layer 21 into the n-type semiconductor layer 21. An appearance of the depletion layer that extends from the p-n junction region to the side of the n-type semiconductor layer 21 is indicated by an arrow Dn-1 in FIG. 3A. Furthermore, the appearance of the depletion layer that extends from the junction region between the anode electrode 11 and the n-type semiconductor layer 21 to the side of the n-type semiconductor layer 21 is indicated by an arrow Dn-2.

In the semiconductor device 1, the multiple p-type semiconductor regions 31 are arranged along a line extending in the Y-direction. Because of this, when applying the reverse bias, a so-called “pinch-off” occurs in which the depletion layers that extend from the adjacent p-n junction regions are linked with one another. Furthermore, the depletion layer that extends from the junction region between the anode electrode 11 and the n-type semiconductor layer 21 into the n-type semiconductor layer 21 is also linked with the above-described linked depletion layers. Moreover, a depletion layer also extends from the base of each of the p-type semiconductor regions 31 into the n-type semiconductor layer 21.

Therefore, the depletion layer extends into the n-type semiconductor layer 21 that is below each of the multiple p-type semiconductor regions 31 and into the n-type semiconductor layer 21 that is between adjacent p-type semiconductor regions 31 (as noted by the arrows parallel to the y-direction). In FIG. 3B, an extent of the depletion layer is indicated by line 21d. The depletion layer extends below each of the multiple p-type semiconductor regions 31. Moreover, the position indicated by the line 21d is one example, and the boundary position may be changed, for example, by changing a material of the anode electrode 11 and/or adjusting dopant concentrations of the n-type semiconductor layer 21 and the p-type semiconductor region 31.

Even without the multiple p-type semiconductor regions 31 being provided, the depletion layer extends from the junction interface between the cathode electrode 10 and the n-type semiconductor layer 21 into the n-type semiconductor layer 21. However, the depletion layer that extends from the p-n junction region is not formed and the depletion layer would, in general, not broaden (extend in the y-direction) as much as is illustrated in FIG. 3B. To put it another way, if the p-type semiconductor regions 31 are not provided, the depletion layer would generally not span between the entire breadth (y-direction) of the anode electrode 11 and the depletion layer would have a boundary positioned to the side of the anode electrode 11 rather than being positioned as indicated by the line 21d in FIG. 3B.

In such a configuration (i.e., without p-type semiconductor regions 31), when applying the reverse bias, there occurs a case in which a so-called reverse leakage electric current cannot be suppressed sufficiently. The reason why the reverse leakage electric current cannot be suppressed is that when applying the reverse bias, the depletion layer does not extend sufficiently, and an electric field gradient of the n-type semiconductor layer 21 is steep within the depletion layer.

In contrast, in the semiconductor device 1, the depletion layer is formed on the n-type semiconductor layer 21 between the adjacent p-type semiconductor regions 31 and on the n-type semiconductor layer 21 that is positioned below each of the multiple p-type semiconductor regions 31. To put it another way, when applying the reverse bias, the electric field gradient of the n-type semiconductor layer 21 is more gentle (less steep) within the depletion layer. As a result, the reverse leakage electric current may be suppressed.

If an occupancy ratio of the p-type semiconductor regions 31 is increased too greatly by, for example, minimizing a pitch between the multiple p-type semiconductor regions 31, the distance between the adjacent p-type semiconductor regions 31 may become extremely small. In such a case, the effective resistance of the n-type semiconductor layer 21 is increased between the adjacent p-type semiconductor regions 31. As a result, a required forward voltage Vf is made to be substantially increased. In the semiconductor device 1, the pitch between the multiple p-type semiconductor regions 31 is set such that an extreme increase in the forward voltage Vf does not occur.

Furthermore, in the semiconductor device 1, the p⁺-type semiconductor region 32 is greater in width than the p-type semiconductor region 31 in the Y-direction. When the p⁺-type semiconductor region 32 becomes smaller in width than the p-type semiconductor region 31, a cross section of the p⁺-type semiconductor region 32 becomes, relatively speaking, the shape of a thin protrusion—that is narrow compare to the individual p-type semiconductor regions 31. In such a case, when applying the reverse bias, the electric field will selectively concentrates at the p⁺-type semiconductor region 32. The selective concentration is a cause of an avalanche (breakdown) electric current. In the semiconductor device 1, the avalanche electric current is prevented by setting the p⁺-type semiconductor region 32 to be greater in width than the p-type semiconductor region 31. According to the first embodiment, the semiconductor device 1 having high withstand voltage is provided in this manner.

### Second Embodiment

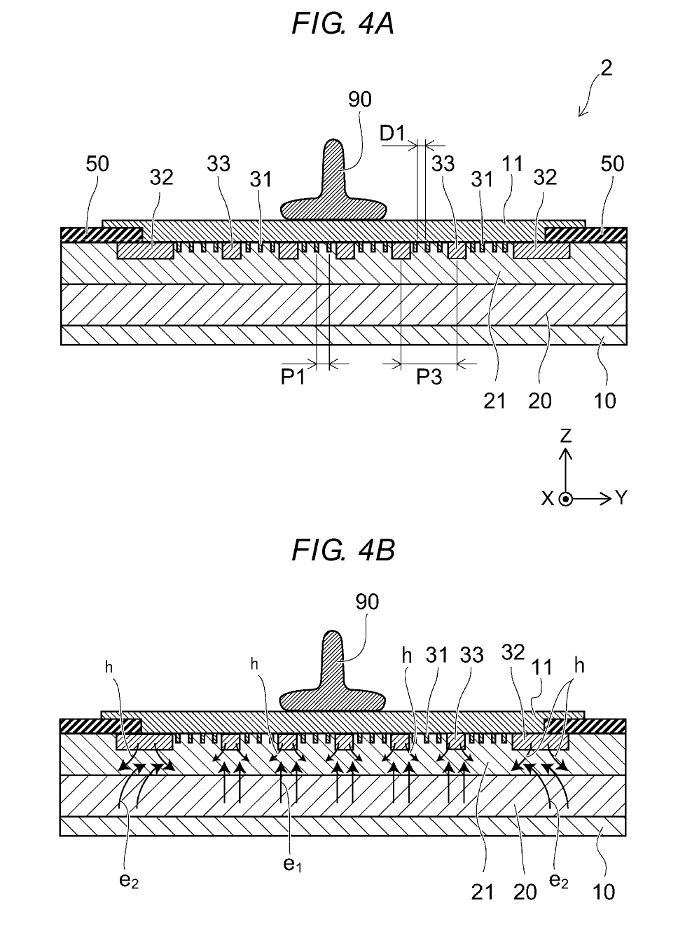

FIG. 4A is a schematic cross-sectional view illustrating a semiconductor device according to a second embodiment, and FIG. 4B is a schematic cross-sectional view illustrating operation of the semiconductor device according to the second embodiment.

A semiconductor device 2 illustrated in FIG. 4A has a Schottky barrier diode (SBD). The semiconductor device 2 includes an anode electrode 11, a cathode electrode 10, multiple p-type semiconductor regions 31, multiple p⁺-type semiconductor regions 33 (a third semiconductor region), an n-type semiconductor layer 21, and an n⁺-type semiconductor layer 20.

A p⁺-type semiconductor region 32 is illustrated in FIG. 4A, but the p⁺-type semiconductor region 32 need not be included in the semiconductor device 2. If the p⁺-type semiconductor region 32 is provided, the p⁺-type semiconductor region 32 is provided in such a manner as to surround the p-type semiconductor regions 31 and the p⁺-type semiconductor regions 33. Furthermore, a concentration of a dopant that is included in the p⁺-type semiconductor region 33 is set to be the same as the concentration of the dopant that is included in the p⁺-type semiconductor region 32.

The p⁺-type semiconductor regions 33 are positioned between the anode electrode 11 and the cathode electrode 10. The p⁺-type semiconductor regions 33 are provided between the n-type semiconductor layer 21 and the anode electrode 11. The p⁺-type semiconductor regions 33 are provided, in this example, within (that is, surrounded by, in the x-y plane,) the p⁺-type semiconductor region 32. The p⁺-type semiconductor regions 33 are arranged along the Y-direction. Each of the p⁺-type semiconductor regions 33 is in contact with the anode electrode 11. A dopant concentration of the p⁺-type semiconductor regions 33 is higher than the dopant concentration of the p-type semiconductor regions 31.

A distance D1 between portions of adjacent p-type semiconductor regions 31 in the Y-direction is smaller than a pitch P3 between p⁺-type semiconductor regions 33. Here, pitch P3 refers to the distance between corresponding portions of adjacent p⁺-type semiconductor regions 33. For example, pitch may measured from center portions (as depicted in the FIG. 4A), left edges, right edges, or any equivalent point of adjacent p⁺-type semiconductor regions 33. In the Y-direction, the pitch P3 between the p⁺-type semiconductor regions 33 is greater than a pitch 1 between the p-type semiconductor regions 31 that are positioned between adjacent p⁺-type semiconductor regions 33. Furthermore, in the Y-direction, each p⁺-type semiconductor region 33 is greater in width than each p-type semiconductor region 31.

With such a construction, when applying a forward bias, as illustrated in FIG. 4B, carriers (holes h) are injected from each of the p⁺-type semiconductor regions 33 into the n-type semiconductor layer 21. To put it another way, conductivity in the n-type semiconductor layer 21 is modulated in the vicinity of each of the p⁺-type semiconductor regions 33. Therefore, the number of electrons e1 that can be injected from the cathode electrode 10 into the n⁺-type semiconductor layer 20 is additionally increased in a state in FIG. 4B, compared to the state in FIG. 2B. To put it another way, when applying forward bias, an amount of electric current that flows between the cathode and anode electrodes is further increased.

Furthermore, because the conductivity modulation occurs in the vicinity of each of the p⁺-type semiconductor regions 33, a forward voltage Vf can be set to a lower value when applying a forward bias. Moreover, even if the amount of electric current that flows between the cathode and anode electrodes is further increased, heat generation between the cathode and anode electrodes is suppressed because the forward voltage Vf can be set to be low.

The semiconductor device 2 also has a p-n junction region that is formed between p-type semiconductor regions 31 and the n-type semiconductor layer 21. Therefore, when applying a reverse bias, a depletion layer broadens into the n-type semiconductor layer 21 that is below each of the p-type semiconductor regions 31 in addition to extending into the n-type semiconductor layer 21 between the adjacent p-type semiconductor regions 31. As a result, a reverse leakage electric current is reliably suppressed.

Furthermore, in the semiconductor device 2 the pitch between the p-type semiconductor regions 31 and the pitch between the p⁺-type semiconductor regions 33 can be adjusted as needed to prevent an extreme increase in the forward voltage Vf.

Also, in the semiconductor device 2, the p⁺-type semiconductor region 33 is greater in width (in the Y-direction) than the p-type semiconductor region 31. When the p⁺-type semiconductor region 33 becomes smaller in width than the p-type semiconductor region 31, a cross section of the p⁺-type semiconductor region 33 becomes the shape of a thin protrusion. In such a case, an electric field would selectively concentrate on the p⁺-type semiconductor region when applying the reverse bias. This selective concentration is a cause of an avalanche electric current.

In the semiconductor device 2, the avalanche electric current level can be controlled by setting the p⁺-type semiconductor region 33 to be greater in width than the p-type semiconductor region 31. Furthermore, even if the breakdown (avalanche) occurs in the semiconductor device 2, the avalanche electric current (for example, a hole electric current) may be discharged through each of the multiple p⁺-type semiconductor regions 33 to the anode electrode 11. To put it another way, a withstand (breakdown) voltage of the semiconductor device 2 is greater than a withstand (breakdown) voltage of the semiconductor device 1.

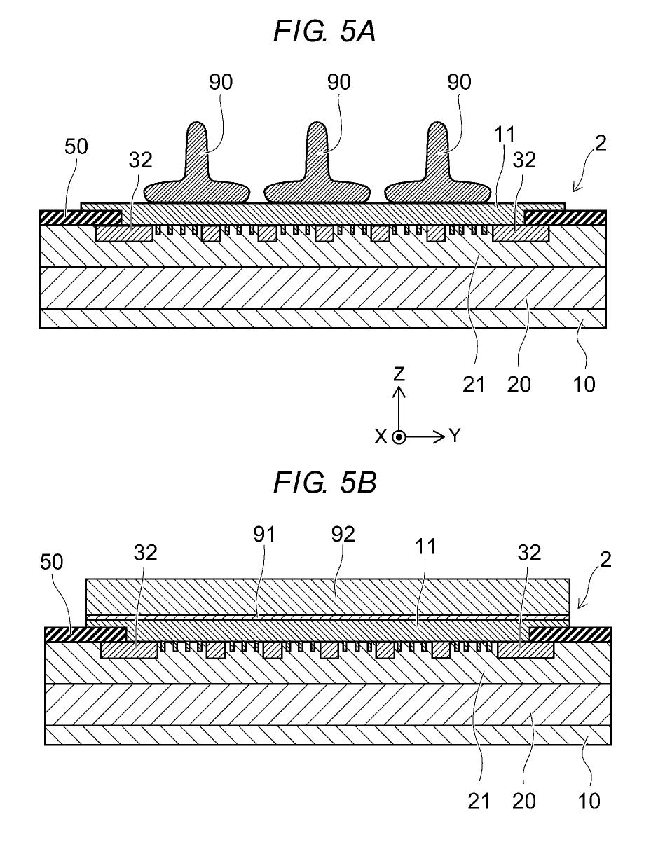

FIG. 5A is a schematic cross-sectional view illustrating the operation of the semiconductor device according to the second embodiment, and FIG. 5B is a schematic cross-sectional view illustrating the operation of the semiconductor device according to the second embodiment.

As illustrated in FIG. 5A, multiple bonding wires 90 may be connected to the anode electrode 11. If one bonding wire 90 is connected to the anode electrode 11, the electric current is concentrated at the one bonding wire 90 when the semiconductor device 2 is turned on. Thus, for example, there is a greater likelihood of the one bonding wire 90 peeling (separating) from the anode electrode 11 or a likelihood of the bonding wire 90 being disconnected due to thermal stresses.

In contrast, as illustrated in FIG. 5A, the electric current that flows between the cathode and anode electrodes is distributed among multiple bonding wires 90. Therefore, the concentration of the electric current at any one bonding wire 90 is reduced, and thus likelihood of the peeling and the disconnection on any one bonding wire 90 is reduced.

Furthermore, as illustrated in FIG. 5B, a conductive layer 92 may be connected to the anode electrode 11 through a conductive adhesion layer 91 such as a solder. The conductive layer 92 may be in the shape of a plate, as depicted in FIG. 5B. Thus, the electric current that flows between the cathode and anode electrodes is distributed within the conductive layer 92. Therefore, the peeling and the disconnection of the bonding wire(s) 90 are prevented.

### Third Embodiment

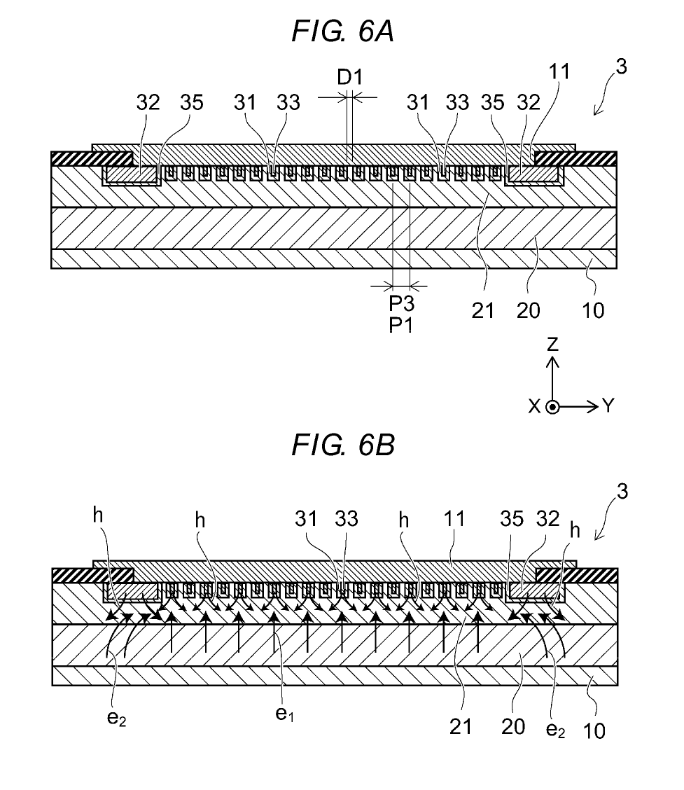

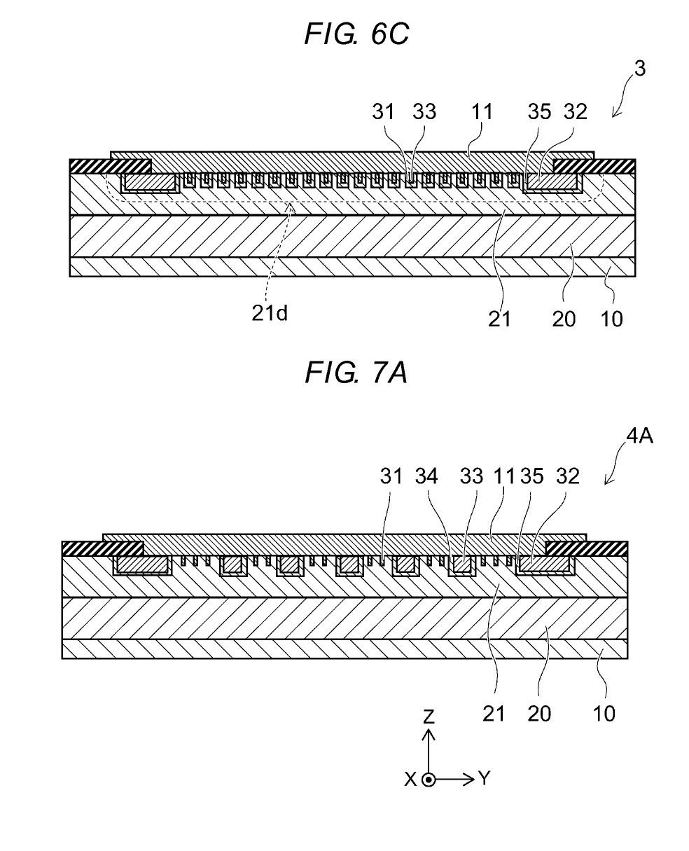

FIG. 6A is a schematic cross-sectional view illustrating a semiconductor device according to a third embodiment, FIG. 6B is a schematic cross-sectional view illustrating operation of the semiconductor device according to the third embodiment, and FIG. 6C is a schematic cross-sectional view illustrating the operation of the semiconductor device according to the third embodiment.

A semiconductor device 3 illustrated in FIG. 6A has a Schottky barrier diode (SBD). The semiconductor device 3 includes an anode electrode 11, a cathode electrode 10, a p⁺-type semiconductor region 32, p⁺-type semiconductor regions 33, a p-type semiconductor region 31, a p-type semiconductor region 35, an n-type semiconductor layer 21, and an n⁺-type semiconductor layer 20.

In the semiconductor device 3, a p⁺-type semiconductor region 33 is provided within each p-type semiconductor region 31. The p⁺-type semiconductor region 33 is in contact with the anode electrode 11, and the portion of the p⁺-type semiconductor region 33 that is not in contact with the anode electrode 11 is surrounded by the p-type semiconductor region 31. In this embodiment, a width in the Y-direction of each of the p⁺-type semiconductor regions 33 is set to be the same as a width in the Y-direction of the p-type semiconductor region 31 illustrated in FIG. 1B.

A dopant concentration of the p⁺-type semiconductor region 33 is higher than a dopant concentration of the p-type semiconductor region 31.

Additionally, p-type semiconductor region 35 is provided between the p⁺-type semiconductor region 32 and the n-type semiconductor layer 21. A dopant concentration of the p-type semiconductor region 35 is lower than a dopant concentration of the p⁺-type semiconductor region 32. The p⁺-type semiconductor region 32 and the p-type semiconductor region 35 are optional and need not be included in the semiconductor device 3.

In the semiconductor device 3, a distance D1, in the Y-direction, between portions of adjacent p-type semiconductor regions 31 is smaller than a pitch P3, in the Y-direction, between the p⁺-type semiconductor regions 33. Furthermore, a pitch P1, in the Y-direction, between the p-type semiconductor regions 31 is the same as the pitch P3 between the multiple p⁺-type semiconductor regions 33.

Thus, when applying a forward bias to the device illustrated in FIG. 6B, carriers (holes h) are injected from each of the p⁺-type semiconductor regions 33 into the n-type semiconductor layer 21. To put it another way, conductivity in the n-type semiconductor layer 21 can be modulated in the vicinity of each of the p⁺-type semiconductor regions 33. Therefore, the number of electrons e1 that can be injected from the cathode electrode 10 into the n⁺-type semiconductor layer 20 is increased in a state depicted in FIG. 6B, compared to the state depicted in FIG. 2B. To put it another way, when applying the forward bias, an amount of electric current that flows between cathode and anode electrodes is increased further in the semiconductor device 3 compared to semiconductor device 1.

Furthermore, because conductivity modulation occurs in the vicinity of each of the p⁺-type semiconductor regions 33, a forward voltage Vf can be set to be lower when applying the forward bias. Thus, even if the amount of electric current that flows between the cathode and anode electrodes is further increased, heat generation between the cathode and anode electrodes is suppressed because the forward voltage Vf can be set to be low.

The semiconductor device 3 has a p-n junction region that is formed from the multiple p-type semiconductor regions 31 and the n-type semiconductor layer 21. Therefore, as illustrated in FIG. 6C, when applying a reverse bias, a depletion layer broadens into the n-type semiconductor layer 21 that is positioned below each of the p-type semiconductor regions 31 in addition to broadening into the n-type semiconductor layer 21 between the adjacent p-type semiconductor regions 31. As a result, a reverse leakage electric current is reliably suppressed. In FIG. 6C, a boundary position of the depletion layer is indicated by line 21d.

Furthermore, in the semiconductor device 3, the pitch between the p-type semiconductor regions 31 and the pitch between the multiple p⁺-type semiconductor regions 33 can be adjusted to prevent an extreme increase in the forward voltage Vf.

Additionally, in the semiconductor device 3, the p-type semiconductor region 31 is provided between the p⁺-type semiconductor region 33 and the n-type semiconductor layer 21. To put it another way, the width, in the Y-direction, of the p-type material that is in contact with the anode electrode 11 is set to be larger. Accordingly, when applying the reverse bias, concentration of an electric field on the p-type regions is alleviated, and thus it is more difficult for an avalanche electric current to occur.

Furthermore, even if the avalanche electric current occurs, in the semiconductor device 3, the avalanche electric current (for example, a hole electric current) may be discharged through each of the multiple p⁺-type semiconductor regions 33 to the anode electrode 11. To put it another way, a withstand (breakdown) voltage of the semiconductor device 3 is higher than the withstand (breakdown) voltage of the semiconductor device 1.

If a semiconductor material of the semiconductor device 3 includes silicon carbide (SiC), there is a likelihood that defects will be formed due to the injection of the impurities into the high-concentration p⁺-type semiconductor regions 32 and 33. If such defects occur, there is a likelihood that leakage from the p⁺-type semiconductor regions 32 and 33 into the anode electrode 11 will occur when a reverse bias is applied.

In the semiconductor device 3, the low-concentration p-type semiconductor regions 31 and 35 are provided between the high-concentration p⁺-type semiconductor regions 32 and 33 and the n-type semiconductor layer 21. Because of this, a depletion layer is formed between the low-concentration p-type semiconductor regions 31 and 35 and the n-type semiconductor layer 21 when applying the reverse bias and thus the leakage electric current is more reliably suppressed.

### Fourth Embodiment

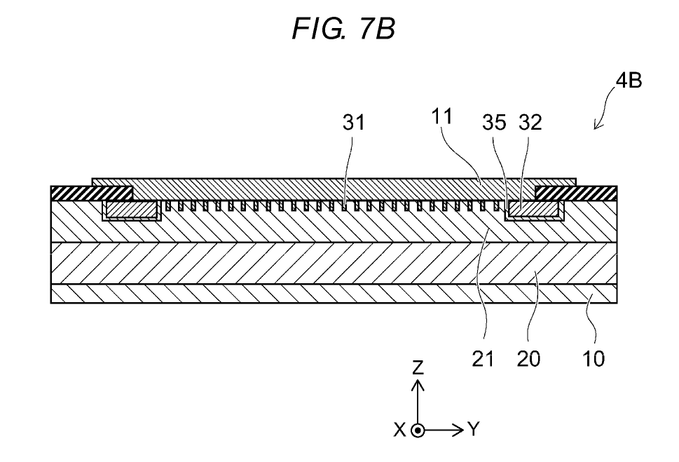

FIG. 7A is a schematic cross-sectional view illustrating a first example of a semiconductor device according to a fourth embodiment, and FIG. 7B is a schematic cross-sectional view illustrating a second example of the semiconductor device according to the fourth embodiment.

In a semiconductor device 4A, illustrated in FIG. 7A, a p-type semiconductor region 34 (a fourth semiconductor region) is provided between each of the p⁺-type semiconductor regions 33 and the n-type semiconductor layer 21. Furthermore, a p-type semiconductor region 35 (a fifth semiconductor region) is provided between the p⁺-type semiconductor region 32 and the n-type semiconductor layer 21. The p⁺-type semiconductor region 32 and the p-type semiconductor region 35 are optional and need not be included in all embodiments.

In the semiconductor device 4A, a p-type semiconductor region 31 is provided between adjacent p-type semiconductor regions 34. With this construction, when a reverse bias is applied a depletion layer broadens from a pn junction region between the p-type semiconductor region 31 and the n-type semiconductor layer 21. As a result, in the semiconductor device 4A, a reverse leakage electric current is further suppressed as compared to the semiconductor device 3.

Furthermore, in addition to a basic construction of the semiconductor device 1, a semiconductor device 4B described in FIG. 7B further includes a p-type semiconductor region 35 that is provided between a p⁺-type semiconductor region 32 and an n-type semiconductor layer 21. Because of this, when a reverse bias is applied, a depletion layer is formed between the low-concentration p-type semiconductor region 35 and the n-type semiconductor layer 21, and thus leakage electric current is reliably suppressed.

According to the embodiments, the p-type may be set as the second conductivity type and the n-type may be set as the first conductivity-type or vice versa.

Furthermore, according to the embodiments, the description “a portion A is provided on a portion B” may be used to mean that the portion A is provided on the portion B with the portion A being in contact with the portion B and to mean that the portion A is provided above the portion B without the portion A being in contact with the portion B. Furthermore, the description “a portion A is provided on a portion B” may be provided to mean that the portion A and the portion B are reversed and thus the portion A is positioned below the portion B, or to mean that the portion A and the portion B are horizontally lined up. This usage is possible because even if the semiconductor device according to the embodiments may be rotated, the construction of the semiconductor is not change before and after rotation.

Furthermore, the elements included in each embodiment described above may be combined as long as combining is technologically possible, and a resulting combination is included in a scope of this disclosure. In addition, the scope of this disclosure includes various modifications that would be apparent to a person of ordinary skill in the art.

While certain embodiments have been described, these embodiments have been presented by way of example only, and are not intended to limit the scope of the inventions. Indeed, the embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device, comprising:
a first electrode;
a second electrode;
multiple first conductivity-type first semiconductor regions that are positioned between the first electrode and the second electrode, are in contact with the first electrode, and are arranged along a first direction intersecting a second direction that extends from the first electrode toward the second electrode;
a first conductivity-type second semiconductor region that is in contact with the first electrode, disposed around the multiple first conductivity-type first semiconductor regions, and has a dopant concentration that is higher than a dopant concentration of the multiple first conductivity-type first semiconductor regions;
a second conductivity-type first semiconductor layer having portions that are between the multiple first conductivity-type first semiconductor regions and the first conductivity-type second semiconductor region and in Schottky contact with the first electrode; and
multiple first conductivity-type third semiconductor regions that are in contact with the first electrode and are bounded by the first conductivity-type second semiconductor region,
wherein the multiple first conductivity-type third semiconductor regions are arranged along the first direction, and have a dopant concentration that is higher than the dopant concentration of the multiple first conductivity-type first semiconductor regions, and a pitch between adjacent first conductivity-type third semiconductor regions that is greater than a pitch between adjacent first conductivity-type first semiconductor regions.

2. The device according to claim 1, further comprising:
a first conductivity-type fourth semiconductor region that is provided between each of the multiple first conductivity-type third semiconductor regions and the first semiconductor layer,
wherein a dopant concentration of the first conductivity-type fourth semiconductor region is lower than the dopant concentration of the multiple first conductivity-type third semiconductor regions.

3. The device according claim 1, wherein the multiple first conductivity-type first semiconductor regions each extend in a third direction orthogonal to the first and second directions.

4. The device according to claim 3, wherein at least one of the multiple first conductivity-type first semiconductor regions extends in the third direction in an intermittent pattern.

5. The device according to claim 1, further comprising a plurality of bonding wires connected to the first electrode.

6. The device according to claim 1, wherein the first conductivity-type second semiconductor region is in ohmic contact with the first electrode.

7. The device according to claim 1, wherein the second conductivity-type first semiconductor layer is a silicon layer.

8. The device according to claim 1, wherein the multiple first conductivity-type first semiconductor regions are p-type regions.

9. A semiconductor device, comprising:
a first electrode;
a second electrode;
multiple first conductivity-type first semiconductor regions that are positioned between the first electrode and the second electrode, are in contact with the first electrode, and are arranged along a first direction intersecting a second direction that extends from the first electrode toward the second electrode;
multiple first conductivity-type second semiconductor regions that are positioned between the first electrode and the second electrode, are in contact with the first electrode, are arranged along the first direction, and have a dopant concentration that is higher than a dopant concentration of the multiple first conductivity-type first semiconductor regions; and
a second conductivity-type first semiconductor layer in Schottky contact with the first electrode and having portions that are between the multiple first conductivity-type first semiconductor regions and the multiple first conductivity-type second semiconductor regions,
wherein a distance between adjacent first conductivity-type first semiconductor regions is less than a pitch between the multiple first conductivity-type second semiconductor regions in the first direction.

10. The device according to claim 9, wherein the pitch between the multiple second semiconductor regions is greater than a pitch between the multiple first conductivity-type first semiconductor regions that are between adjacent first conductivity-type second semiconductor regions.

11. The device according to claim 9, further comprising:
a first conductivity-type second semiconductor region having a dopant concentration that is higher than the dopant concentration of the multiple first conductivity-type first semiconductor regions,
wherein the first conductivity-type second semiconductor region is in contact with the first electrode, and encircles the first conductivity-type multiple first semiconductor regions and the multiple first conductivity-type second semiconductor regions.

12. The device according to claim 9, further comprising:
a first conductivity-type third semiconductor region that is between each of the multiple second first conductivity-type semiconductor regions and the second conductivity-type first semiconductor layer, the first conductivity-type third semiconductor region having a dopant concentration that is lower than the dopant concentration of the multiple first conductivity-type second semiconductor regions.

13. The device according to claim 11, further comprising:
a first conductivity-type fourth semiconductor region that is between the first conductivity-type second semiconductor region and the second conductivity-type first semiconductor layer, the first conductivity-type fourth semiconductor region having a dopant concentration that is lower than the dopant concentration of the first conductivity-type second semiconductor region.

14. The device according to claim 9, wherein at least one of the multiple first conductivity-type first semiconductor regions, at least one of the multiple first conductivity-type second semiconductor regions, or the second conductivity-type first semiconductor layer is silicon carbide (SiC).

15. A semiconductor device, comprising:
a first electrode;
a second electrode;
multiple first conductivity-type first semiconductor regions that are between the first electrode and the second electrode, are in contact with the first electrode, and are arranged along a first direction intersecting a second direction that extends from the first electrode toward the second electrode;
a plurality of first conductivity-type second semiconductor regions that are each in contact with the first electrode, and have a dopant concentration that is higher than a dopant concentration of the multiple first conductivity-type first semiconductor regions, each of the multiple first conductivity-type first semiconductor regions surrounding one of the first conductivity-type second semiconductor regions at portions that are not in contact with the first electrode; and
a second conductivity-type first semiconductor layer that is between the first electrode and the second electrode, and between the multiple first conductivity-type first semiconductor regions and the multiple first conductivity-type second semiconductor regions, and is in Schottky contact with the first electrode.

16. The semiconductor device of claim 15, wherein a distance in the first direction between adjacent first conductivity-type first semiconductor regions is less than a pitch between the multiple first conductivity-type second semiconductor regions.

17. The device according to claim 15, wherein a pitch in the first direction between the multiple first conductivity-type first semiconductor regions is the same as the pitch in the first direction between the multiple first conductivity-type second semiconductor regions, and
each first conductivity-type first semiconductor region is between each of the multiple third semiconductor regions and the first semiconductor layer.

18. The device according to claim 15, further comprising a first conductivity-type third semiconductor region that is in contact with the first electrode, disposed around the multiple first conductivity-type first semiconductor regions, and has a dopant concentration that is higher than a dopant concentration of the multiple first conductivity-type first semiconductor regions.

19. The device according to claim 15, further comprising a first conductivity-type third semiconductor region that is in contact with the first electrode and has a dopant concentration that is higher than a dopant concentration of the multiple first conductivity-type first semiconductor regions, wherein the multiple first conductivity-type first semiconductor regions are between portions of the third semiconductor layer in the at least one of the first direction and the third direction.
